(19) United States
(12) Patent Application Publication
(10) Pub. No.: US 2022/0238413 A1
(43) Pub. Date: Jul. 28, 2022

(54) DOUBLE SIDED COOLING MODULE WITH POWER TRANSISTOR SUBMODULES

(71) Applicant: Infineon Technologies AG, Neubiberg (DE)

(72) Inventor: Andreas GRASSMANN, Regensburg (DE)

(73) Assignee: Infineon Technologies AG, Neubiberg (DE)

(21) Appl. No.: 17/155,215

(22) Filed: Jan. 22, 2021

(51) Int. Cl. H01L 23/373; H01L 23/495; H01L 23/367; H01L 23/00; H01L 25/07

(52) U.S. Cl. CPC H01L 23/3735; H01L 23/49568; H01L 25/072; H01L 24/72; H01L 23/367

(57) ABSTRACT

A double sided cooling module that includes a leadframe with a top Direct Copper Bonded (DCB) substrate and two or more power transistor submodules. Each one of the power transistor submodules includes a bottom DCB substrate, a spaced-apart row of first wires attached to a top metal layer of the bottom DCB substrate proximate to the first side of the top metal layer, a semiconductor die having a bottom side load path contact attached to a top surface of a die pad portion of the top metal layer, a top side control contact electrically coupled via at least one bond wire to a top surface of a control pad portion of the top metal layer, and an electrically conductive and thermally conductive spacer that is attached to the top side load path contact and to a bottom metal layer of the top DCB substrate. At least one of the first wires is attached to the control pad portion of the top metal layer and to a bottom metal layer of the top DCB substrate. Other ones of the first wires are attached to the die pad portion of the top metal layer and to the bottom metal layer of the top DCB substrate.

### FIELD OF TECHNOLOGY

The present application relates to a double sided cooling module. More specifically, the present disclosure relates to a double sided cooling module that includes two or more power transistor submodules.

### BACKGROUND

Conventional double sided cooling (DSC) modules can only be electrically tested after a full assembly. This is a problem, for example with MOSFETs such as Silicon Carbide (SiC) MOSFETs, because a number of SiC MOSFETs must be connected in parallel within a DSC module in order to achieve a required switching current rating. If electrical testing is performed on the DSC module and some of the SiC MOSFETs within the DSC module cause the DSC module to fail the electrical test, the DSC module is rejected. Rejecting a DSC module that includes SiC MOSFETs that individually pass the electrical test can significantly reduce the overall yield of the DSC modules being tested. Furthermore, because SiC MOSFETs are relatively expensive to manufacture compared to other types of MOSFETs, additional costs are incurred because the SiC MOSFETs that individually pass the electrical test cannot be reused. Another problem with conventional DSC modules is that all parts, including the SiC MOSFETs used in the DSC module, have to be designed specifically for the power class or required switching current rating that the DSC modules are intended to be used for. This can significantly increase the cost of the DSC module.

For these and other reasons, there is a need for the present invention.

### SUMMARY

According to an embodiment of a submodule for a double sided cooling module, the submodule includes a Direct Copper Bonded (DCB) substrate that includes a top metal layer and a bottom metal layer separated by an insulation layer. The top metal layer has a first side, a second side and a center equidistant from the first side and the second side in a direction parallel with a plane of the top metal layer. The DCB substrate includes a spaced-apart row of first wires that each have a top end and a bottom end, where the bottom end of each of the first wires is attached to the top metal layer proximate to the first side of the top metal layer. The first wires extend in an upward direction from the first metal layer. A semiconductor die includes a top side load path contact, a top side control contact and a bottom side load path contact. The bottom side load path contact is attached to a top surface of a die pad portion of the top metal layer, and the top side control contact is electrically coupled via at least one bond wire to a top surface of a control pad portion of the top metal layer that is electrically isolated from the die pad portion. At least one of the first wires is attached to the control pad portion of the top metal layer, and other ones of the first wires are attached to the die pad portion of the top metal layer. An electrically conductive and thermally conductive spacer is over the semiconductor die and is attached to the top side load path contact of the semiconductor die. The top end of the first wires have a height perpendicular to the plane of the first metal layer that is greater than a height of a top side of the spacer from the plane of the first metal layer.

According to an embodiment of a double sided cooling module, the double sided cooling module includes a leadframe with a top Direct Copper Bonded (DCB) substrate that includes a top metal layer and a bottom metal layer separated by an insulation layer. The leadframe is attached to the bottom metal layer. The double sided cooling module includes two or more power transistor submodules. Each one of the power transistor submodules includes a bottom DCB substrate that includes a top metal layer and a bottom metal layer separated by an insulation layer. The top metal layer of the bottom DCB substrate has a first side, a second side and a center equidistant from the first side and the second side in a direction parallel with a plane of the top metal layer of the bottom DCB substrate. Each one of the power transistor submodules includes a spaced-apart row of first wires that each have a top end and a bottom end, where the bottom end of each of the first wires is attached to the top metal layer of the bottom DCB substrate proximate to the first side of the top metal layer of the bottom DCB substrate. Each one of the power transistor submodules includes a semiconductor die that includes a top side load path contact, a top side control contact and a bottom side load path contact. The bottom side load path contact is attached to a top surface of a die pad portion of the top metal layer of the bottom DCB substrate, and the top side control contact electrically coupled via at least one bond wire to a top surface of a control pad portion of the top metal layer of the bottom DCB substrate that is electrically isolated from the die pad portion. At least one of the first wires is attached to the control pad portion of the top metal layer of the bottom DCB substrate and to the bottom metal layer of the top DCB substrate to conductively couple the top side control contact to the bottom metal layer of the top DCB substrate. Other ones of the first wires are attached to the die pad portion of the top metal layer of the bottom DCB substrate and to the bottom metal layer of the top DCB substrate to electrically couple the bottom side load path contact to the bottom metal layer of the top DCB substrate. An electrically conductive and thermally conductive spacer is over the semiconductor die and is attached to the top side load path contact of the semiconductor die. The spacer conductive couples the top side load path contact to the bottom metal layer of the top DCB substrate.

According to an embodiment of a method of forming a submodule, the method includes providing a Direct Copper Bonded (DCB) substrate that includes a top metal layer and a bottom metal layer separated by an insulation layer. The top metal layer has a first side, a second side and a center equidistant from the first side and the second side in a direction parallel with a plane of the top metal layer. The top metal layer includes a die pad portion and a control pad portion that is electrically isolated from the die pad portion, where the control pad portion is proximate to the first side of the top metal layer. The method includes placing a first solder preform layer on a top surface of the die pad portion of the top metal layer. The method includes placing a semiconductor die on a top surface of the first solder preform layer, where the semiconductor die includes a top side load path contact, a top side control contact and a bottom side load path contact. The method includes placing a second solder preform layer on a top surface of the top side load path contact of the semiconductor die. The method includes placing an electrically conductive and thermally conductive spacer over the second solder preform layer. The method includes reflowing the first solder preform layer and the second solder preform layer to attach the bottom side load path contact of the semiconductor die to the die pad portion of the top metal layer and to attach the spacer to the top side load path contact of the semiconductor die. The method includes attaching at least one bond wire between the top side control contact of the semiconductor die and the control pad portion of the top metal layer. The method includes attaching a bottom end of each one of a spaced-apart row of first wires to the top metal layer proximate to the first side of the top metal layer such that each one of the first wires extends in an upward direction from the first metal layer and a top end of the first wires have a height perpendicular to the plane of the first metal layer that is greater than a height of a top side of the spacer from the plane of the first metal layer. At least one of the first wires is attached to the control pad portion of the top metal layer, and other ones of the first wires are attached to the die pad portion of the top metal layer.

According to an embodiment of a method of forming a double sided cooling module, the method includes providing a leadframe with a top Direct Copper Bonded (DCB) substrate that includes a top metal layer and a bottom metal layer separated by an insulation layer, where the leadframe is attached to the bottom metal layer. The method includes providing two or more power transistor submodules, where each power transistor submodule includes a bottom DCB substrate that includes a top metal layer and a bottom metal layer separated by an insulation layer, where the top metal layer of the bottom DCB substrate has a first side, a second side and a center equidistant from the first side and the second side in a direction parallel with a plane of the top metal layer of the bottom DCB substrate. The two or more power transistor submodules each include a spaced-apart row of first wires that each have a top end and a bottom end, where the bottom end of each of the first wires is attached to the top metal layer of the bottom DCB substrate proximate to the first side of the top metal layer of the bottom DCB substrate. The two or more power transistor submodules each include a semiconductor die that includes a top side load path contact, a top side control contact and a bottom side load path contact. The bottom side load path contact is attached to a top surface of a die pad portion of the top metal layer of the bottom DCB substrate, the top side control contact is electrically coupled via at least one bond wire to a top surface of a control pad portion of the top metal layer of the bottom DCB substrate that is electrically isolated from the die pad portion. At least one of the first wires is attached to the control pad portion of the top metal layer of the bottom DCB substrate, and other ones of the first wires are attached to the die pad portion of the top metal layer of the bottom DCB substrate. The two or more power transistor submodules each include an electrically conductive and thermally conductive spacer over the semiconductor die that is attached to the top side load path contact of the semiconductor die. The method includes printing a solder on selected portions of the bottom metal layer of the top DCB substrate. The method includes placing a leadframe such that portions of the leadframe contact the solder. The method includes placing the two or more power transistor submodules such that a top side of the spacer, the top end of the one of the first wires and the top ends of the other ones of the first wires contact the solder. The method includes reflowing the solder under a pressure from a top metal piece and a bottom metal piece that are coplanar and have a distance between a lower surface of the top metal piece and an upper surface of the bottom metal piece that corresponds to a required thickness of the double sided cooling module, where the top metal piece apples a downward pressure against the top metal layer of the top DCB substrate, and where the bottom metal piece applies an upward pressure against the bottom metal layer of the bottom DBC substrate for each one of the two or more power transistor submodules, and where the reflowing of the solder attaches the top side of the spacer, the top end of the one of the first wires and the top ends of the other ones of the first wires to the bottom metal layer of the top DCB substrate.

Those skilled in the art will recognize additional features and advantages upon reading the following detailed description, and upon viewing the accompanying drawings.

### BRIEF DESCRIPTION OF THE DRAWINGS

The elements of the drawings are not necessarily to scale relative to each other. Like reference numerals designate corresponding similar parts. The features of the various illustrated embodiments can be combined unless they exclude each other. Embodiments are depicted in the drawings and are detailed in the description which follows.

FIGS. 1A-1B illustrate an embodiment of a side view and a top view of a submodule.

FIG. 2 illustrates an embodiment of a partial side view of the submodule illustrated in FIGS. 1A-1B.

FIGS. 3A-3B illustrate embodiments of top views of a submodule.

FIG. 4 illustrates an embodiment of a double sided cooling module with two submodules.

FIG. 5 illustrates an embodiment of a partial top view of a double sided cooling module that includes submodules connected together in a half-bridge configuration.

FIG. 6 illustrates an embodiment of a method of forming a double sided cooling module.

FIGS. 7A-7B illustrate an embodiment of a side view and a top view of a submodule.

FIGS. 8A-8B illustrate embodiments of top views of a submodule.

FIG. 9 illustrates an embodiment of a double sided cooling module.

FIGS. 10A-10C illustrate an embodiment of a spring washer.

FIG. 11 illustrates an embodiment of a method of forming a double sided cooling module.

FIG. 12 illustrates an embodiment of a partial top view of a double sided cooling module that includes submodules connected together in a half-bridge configuration.

FIG. 13 illustrates an embodiment of a method of forming a submodule.

### DETAILED DESCRIPTION

In the following Detailed Description, reference is made to the accompanying drawings, which form a part hereof, and in which is shown by way of illustration specific embodiments in which the invention may be practiced. In this regard, directional terminology, such as “top,” “bottom,” “front,” “back,” “leading,” “trailing”, “upper,” “lower,” “right”, “left”, “vertical,” “horizontal” etc., is used with reference to the orientation of the Figure(s) being described. Because components of embodiments can be positioned in a number of different orientations, the directional terminology is used for purposes of illustration and is in no way limiting.

As employed in this specification, the terms “bonded”, “attached”, “connected”, “coupled” and/or “electrically connected/electrically coupled” are not meant to mean that the elements or layers must directly be contacted together; intervening elements or layers may be provided between the “bonded”, “attached”, “connected”, “coupled” and/or “electrically connected/electrically coupled” elements, respectively. However, in accordance with the disclosure, the above-mentioned terms may, optionally, also have the specific meaning that the elements or layers are directly contacted together, i.e. that no intervening elements or layers are provided between the “bonded”, “attached”, “connected”, “coupled” and/or “electrically connected/electrically coupled” elements, respectively.

Furthermore, the word “over” used with regard to a part, element or material layer formed or located “over” a surface may be used herein to mean that the part, element or material layer be located (e.g. placed, formed, deposited, etc.) indirectly on the implied surface with the part, element or material layer or layers being arranged between the implied surface and the part, element or material layer. However, the word “over” used with regard to a part, element or material layer formed or located “over” a surface may optionally also have the specific meaning that the part, element or material layer be located (e.g. placed, formed, deposited, etc.) directly on, e.g. in direct contact with, the implied surface.

The semiconductor die may be of different types, may be manufactured by different technologies and may include, for example, integrated electrical, electro-optical or electro-mechanical circuits and/or passive devices. The semiconductor die may, for example, be logic integrated circuits, analog integrated circuits, mixed signal integrated circuits, power integrated circuits, memory circuits or passive devices. They may include control circuits, microprocessors or microelectromechanical components. The semiconductor die can include, but are not limited to, a power semiconductor die, a Metal Oxide Semiconductor Field-effect Transistor (MOSFET) such as a Silicon Metal Oxide Semiconductor Field-effect Transistor (Si MOSFET) or a Silicon Carbide MOSFET (SiC MOSFET), an Insulated Gate Bipolar Transistor (IGBT), a Gallium Nitride (GaN) device, a Junction Gate Field Effect Transistor (JFET), as well as power bipolar transistors or power diodes.

The integrated circuit packages, lead frames and lead frame modules described herein may include packages such as a Transistor Outline (TO) package, a Quad Flat No Leads Package (QFN) package, a Small Outline (SO) package, a Small Outline Transistor (SOT) package, a Thin Small Outline Package (TSOP) package, a Dual Small Outline Package (DSO) and a Double Sided Cooling (DSC) package. The leadframe modules can include one or multiple semiconductor die on a same die pad or on different die pads of the leadframe module.

It is to be understood that the features of the various exemplary embodiments described herein may be combined with each other, unless specifically noted otherwise. It is to be understood that other embodiments may be utilized and structural or logical changes may be made without departing from the scope of the present invention. The following detailed description, therefore, is not to be taken in a limiting sense, and the scope of the present invention is defined by the appended claims.

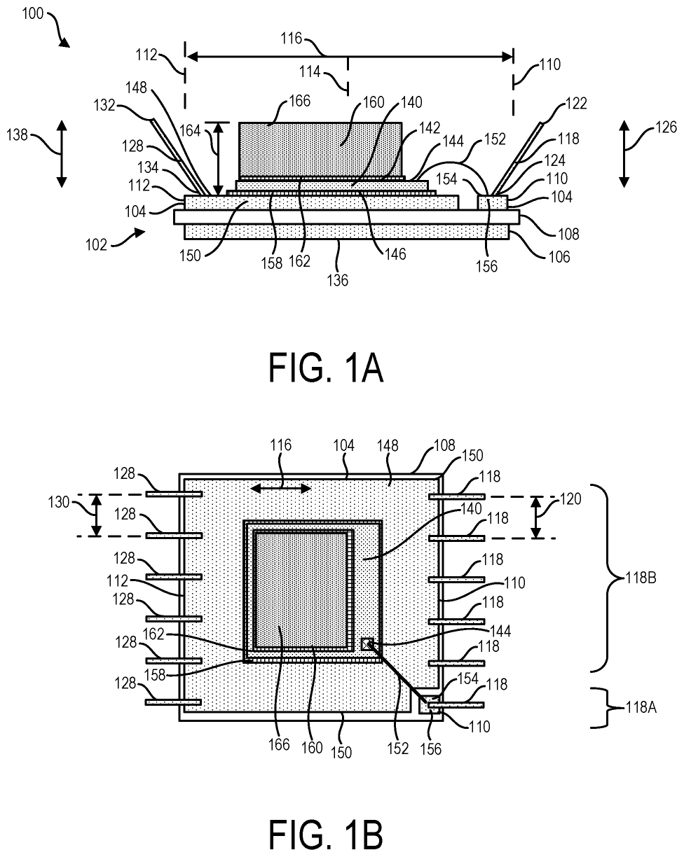

FIGS. 1A-1B illustrate an embodiment of a side view and a top view of a submodule at 100. Referring to FIG. 1A and 1B, submodule 100 includes a Direct Copper Bonded (DCB) substrate 102 that includes a top metal layer 104 and a bottom metal layer 106 that are separated by an insulation layer 108. The top metal layer 104 has a first side 110, a second side 112 and a center 114 equidistant from the first side 110 and the second side 112 in a direction parallel with a plane 116 of the top metal layer 104. A spaced-apart row of first wires 118 as illustrated at 120 each have a top end 122 and a bottom end 124. The bottom end 124 of each of the first wires 118 is attached to the top metal layer 104 proximate to the first side 110 of the top metal layer 104. The first wires 118 extend in an upward direction as illustrated at 126 from the first metal layer 104. Submodule 100 includes a spaced-apart row of second wires 128 as illustrated at 130 that each have a top end 132 and a bottom end 134. A bottom end 134 of each of the second wires 128 is attached to a die pad portion 150 of the top metal layer 104 proximate to the second side 112 of the top metal layer 104. The second wires 128 extend in an upward direction as illustrated at 138 from the first metal layer 104.

In the illustrated embodiment, a semiconductor die 140 includes a top side load path contact 142, a top side control contact 144 and a bottom side load path contact 146. The bottom side load path contact 146 is attached to a top surface 148 of a die pad portion 150 of the top metal layer 104. The top side control contact 144 is electrically coupled via at least one bond wire 152 to a top surface 154 of a control pad portion 156 of the top metal layer 104. The control pad portion 156 is proximate to the first side 110 of the top metal layer 104. The control pad portion 156 is electrically isolated from the die pad portion 150. At least one of the first wires 118 as illustrated at 118A is attached to the control pad portion 156 of the top metal layer 104, and other ones of the first wires 118 as illustrated at 118B are attached to the die pad portion 150 of the top metal layer 104. A first solder layer 158 is on a top surface 148 of the die pad portion 150 of the top metal layer 104. The first solder layer 158 attaches and electrically couples the semiconductor die 140 to the die pad portion 150 of the top metal layer 104. An electrically conductive and thermally conductive spacer 160 is over the semiconductor die 140 and is attached to the top side load path contact 142 of the semiconductor die 140. A second solder layer 162 is on a top surface of the top side load path contact 142 of the semiconductor die 140. The second solder layer 162 attaches and electrically couples the spacer 160 to the top side load path contact 142 of the semiconductor die 140.

In one embodiment, the top end 122 of the first wires 118 have a height 126 perpendicular to the plane 116 of the first metal layer 104 that is greater than a height 164 of a top side 166 of the spacer 160 from the plane 116 of the first metal layer 104. In one embodiment, the top end 132 of the second wires 128 have a height 138 perpendicular to the plane 116 of the first metal layer 104 that is greater than a height 164 of the top side 166 of the spacer 160 from the plane 116 of the first metal layer 104. In one embodiment, a first length between the top end 122 and the bottom end 124 of the first wires 118 is approximately the same. In one embodiment, each one of the first wires 118 are straight and parallel with every other one of the first wires 118. In one embodiment, each one of the second wires 128 are straight and parallel with every other one of the second wires 128. In one embodiment, the first wires 118 are copper (Cu) first wires 118 and the second wires 128 are Cu second wires 128. In one embodiment, a first length between the top end 122 and the bottom end 124 of the first wires 118 is approximately equal to a second length between the top end 132 and the bottom end 134 of the second wires 128.

In the illustrated embodiment, semiconductor die 140 can be a Silicon Metal Oxide Semiconductor Field-effect Transistor (Si MOSFET), an Insulated Gate Bipolar Transistor (IGBT), a Gallium Nitride (GaN) power transistor or a Silicon Carbide MOSFET (SiC MOSFET). In other embodiments, semiconductor die 140 can be other suitable types of power devices. In one embodiment, the semiconductor die 140 is a SiC MOSFET, and the top side load path contact 142 is a source contact, the top side control contact 144 is a gate contact, and the bottom side load path contact 146 is a drain contact. In one embodiment, the semiconductor die 140 is an IGBT, and the top side load path contact 142 is an emitter contact, the top side control contact 144 is a gate contact, and the bottom side load path contact 146 is a collector contact.

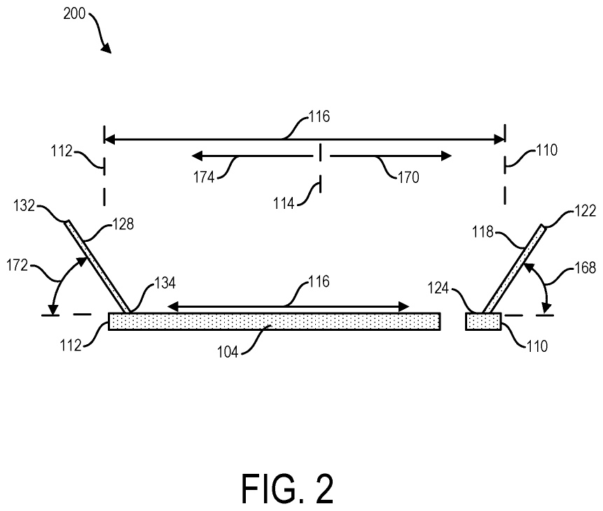

FIG. 2 illustrates an embodiment at 200 of a partial side view of submodule 100 illustrated in FIGS. 1A-1B. The partial side view at 200 includes the first metal layer 104, the first wires 118 and the second wires 128. Referring to FIGS. 1A-1B, a first angle 168 of each of the first wires 118 in a first direction 170 from the center 114 to the first side 110 of the top metal layer 104 relative to the plane 116 of the first metal layer 104 is greater than 45 degrees and less than 90 degrees. A second angle 172 of each of the second wires 128 in a second direction 174 from the center 114 to the second side 112 of the top metal layer 104 relative to the plane 116 of the top metal layer 104 is greater than 45 degrees and less than 90 degrees. In one embodiment, the first angle 168 is equal to the second angle 172.

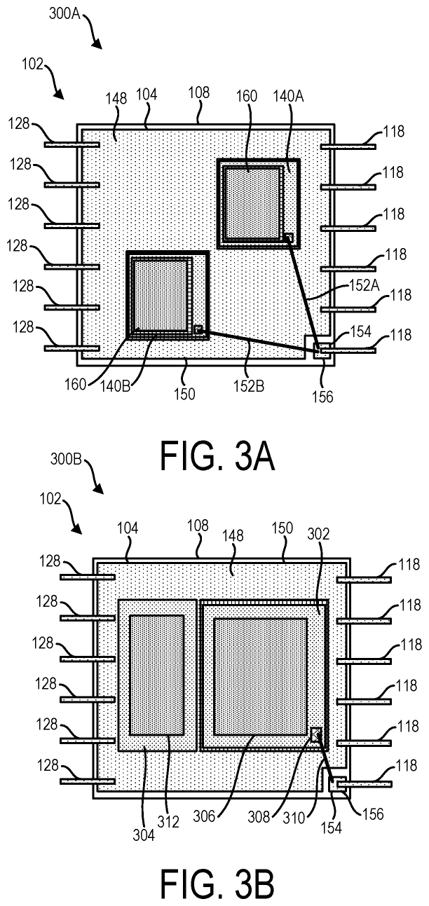

FIGS. 3A-3B illustrate embodiments of top views of a submodule at 300A and 300B. Submodules 300A and 300B utilize a DCB substrate 102, first wires 118 and second wires 128 as illustrated in FIGS. 1A-1B. Referring to FIG. 3A, submodule 300A includes two semiconductor die 140A and 140B that are connected in parallel as opposed to one semiconductor die 140 as illustrated in FIGS. 1A-1B. The electrical connections for semiconductor die 140A and 140B are described with respect to FIGS. 1A-1B and semiconductor die 140. In other embodiments, submodule 300A can include more than two semiconductor die 140.

Referring to FIG. 3B, Submodule 300B includes an IGBT 302 and an anti-parallel diode 304. IGBT 302 includes a top side load path contact which is an emitter contact that is attached to and electrically coupled to a spacer 306. IGBT 302 includes a top side control contact 308 which is a gate contact which is electrically coupled via at least one bond wire 310 to a top surface 154 of a control pad portion 156 of the top metal layer 104. IGBT 302 includes a bottom side load path contact which is a collector contact which is attached to and electrically coupled to a top surface 148 of a die pad portion 150 of the top metal layer 104. Anti-parallel diode 304 includes an anode contact which is attached to and electrically coupled to a spacer 312. Anti-parallel diode includes a cathode contact which is attached to and electrically coupled to the top surface 148 of the die pad portion 150 of the top metal layer 104.

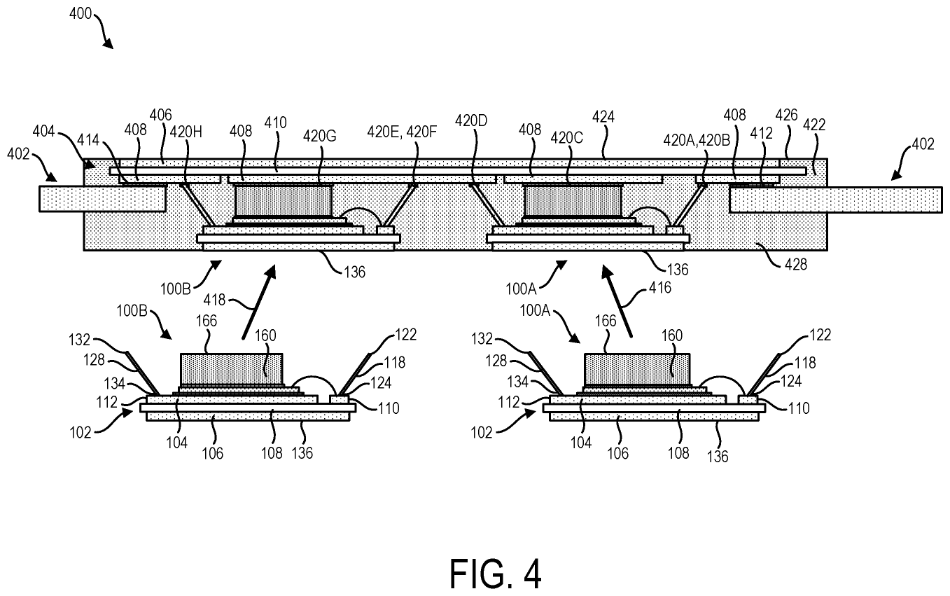

FIG. 4 illustrates an embodiment of a double sided cooling module with two submodules at 400. Double sided cooling module 400 includes a leadframe 402 with a top Direct Copper Bonded (DCB) substrate 404 that includes a top metal layer 406 and a bottom metal layer 408 that are separated by an insulation layer 410. The leadframe 402 is attached to and electrically coupled to the bottom metal layer 408 via solder connections 412 and 414. Double sided cooling module 400 includes two power transistor submodules 100 which are illustrated as 100A and 100B. Power transistor submodule 100A and 100B are described with respect to FIGS. 1A-2. In other embodiments, double sided cooling module 400 can include more than two power transistor submodules 100.

In the illustrated embodiment, power transistor submodules 100A and 100B each include a bottom DCB substrate 102 that includes a top metal layer 104 and a bottom metal layer 106 that are separated by an insulation layer 108. The top metal layer 104 has a first side 110, a second side 112 and a center 114 equidistant from the first side 110 and the second side 112 in a direction parallel with a plane 116 of the top metal layer 104 (See also, FIGS. 1A-2). A spaced-apart row of first wires 118 as illustrated at 120 each have a top end 122 and a bottom end 124, and a spaced-apart row of second wires 128 as illustrated at 130 each have a top end 132 and a bottom end 134. A semiconductor die 140 includes a top side load path contact 142, a top side control contact 144 and a bottom side load path contact 146, where the bottom side load path contact 146 is attached to a top surface 148 of a die pad portion 150 of the top metal layer 104 (See also, FIGS. 1A-2). The top side control contact 144 is electrically coupled via at least one bond wire 152 to a top surface 154 of a control pad portion 156 of the top metal layer 104 (See also, FIGS. 1A-2). At least one of the first wires 118 is attached to the control pad portion 156 of the top metal layer 104, and other ones of the first wires 118 are attached to the die pad portion 150 of the top metal layer 104 (See also, FIGS. 1A-2). An electrically conductive and thermally conductive spacer 160 is over the semiconductor die 140 and is attached to the top side load path contact 142 of the semiconductor die 140 (See also, FIGS. 1A-2).

In the illustrated embodiment, for each power transistor submodule 100A and 100B, a first angle 168 of each of the first wires 118 in a first direction 170 from the center 114 to the first side 110 of the top metal layer 104 relative to the plane 116 of the top metal layer 104 is greater than 45 degrees and less than 90 degrees (See also, FIG. 2). For each power transistor submodule 100A and 100B, a second angle 172 of each of the second wires 128 in a second direction 174 from the center 114 to the second side 112 of the top metal layer 104 relative to the plane 116 of the top metal layer 104 is greater than 45 degrees and less than 90 degrees (See also, FIG. 2). In one embodiment, the first angle 168 is equal to the second angle 172.

In the illustrated embodiment, least one of the first wires 118 for each power transistor submodule 100A and 100B is attached to the control pad portion 156 of the top metal layer 104 of the bottom DCB substrate 102 and a top end 122 of the each one of the first wires 118 is conductively coupled and attached to the bottom metal layer 408 of the top DCB substrate 402 via respective solder connections 420A and 420E. Other ones of the first wires 118 for each power transistor submodule 100A and 100B are attached to the die pad portion 150 of the top metal layer 104 of the bottom DCB substrate 102 and to the bottom metal layer 408 of the top DCB substrate 404 to electrically couple the bottom side load path contact 146 of semiconductor die 140 to the bottom metal layer 408 of the top DCB substrate 404 via respective solder connections 420B and 420F. The second wires 128 for each power transistor submodule 100A and 100B are attached to the die pad portion 150 of the top metal layer 104 of the bottom DCB substrate 102 and to the bottom metal layer 408 of the top DCB substrate 404 to electrically couple the bottom side load path contact 146 of semiconductor die 140 to the bottom metal layer 408 of the top DCB substrate 404 via respective solder connections 420D and 420H. The spacer 160 for each power transistor submodule 100A and 100B is attached at a top end 166 to the bottom metal layer 408 of the top DCB substrate 404 to electrically couple the top side load path contact 142 of semiconductor die 140 to the bottom metal layer 408 of the top DCB substrate 404 via respective solder connections 420C and 420G. A mold compound 422 encapsulates a portion of the leadframe 402, the top DBC substrate 404 and power transistor submodules 100A and 100B such that a top surface 424 of the top metal layer 406 of the top DBC substrate 404 is exposed at a top surface 426 of the mold compound 422. A bottom surface 136 of the bottom metal layer 106 of the bottom DBC substrate 102 for each power transistor submodule 100A and 100B is exposed at a bottom surface 428 of the mold compound 422.

Although the different portions of bottom metal layer 408 of the top DCB substrate 404 are collectively referred to as bottom metal layer 408, it is understood that the top side load path contact 142, the top side control contact 144 and the bottom side load path contact 146 of semiconductor die 140 within each of the transistor submodules 100A and 100B are connected in a parallel arrangement. The one of the first wires 118 for each power transistor submodule 100A and 100B is conductively coupled to and attached to a first portion of bottom metal layer 408 of the top DCB substrate 404 and the other ones of the first wires 118 for each power transistor submodule 100A and 100B are conductively coupled to and attached to a second portion of the bottom metal layer 408 of the top DCB substrate 404 that is electrically isolated from the first portion of the bottom metal layer 408. The second wires 128 for each power transistor submodule 100A and 100B are conductively coupled to and attached to the second portion of bottom metal layer 408 of the top DCB substrate 404, and the spacer 160 is conductively coupled to and attached to a third portion of bottom metal layer 408 of the top DCB substrate 404 that is electrically isolated from both the first portion and the second portion of the bottom metal layer 408.

During formation or manufacturing of double sided cooling module 400, arrow 416 illustrates placement and attachment via solder connections 420A, 420B, 420C and 420D for power transistor submodule 100A against bottom metal layer 408 of top DCB substrate 404, and arrow 418 illustrates placement and attachment via solder connections 420E, 420F, 420G and 420H for power transistor submodule 100B against bottom metal layer 408 of top DCB substrate 404 via arrow 418. Each power transistor submodule 100A and 100B can be electrically tested before placement and attachment to ensure each power transistor submodule 100A and 100B meets a desired electrical specification. This increases a yield of double sided cooling module 400 because failure of one of the power transistor submodule 100A and 100B would result in the double sided cooling module 400 failing a final electrical test which would result in both power transistor submodules 100A and 100B being scrapped.

In the illustrated embodiment, two power transistor submodule 100A and 100B are illustrated. In one embodiment, each power transistor submodule 100A and 100B is designed for a particular power class or switching current rating. If double sided cooling module 400 requires a higher power class or an increased switching current rating, because the top side control contact 144 and the bottom side load path contact 146 of semiconductor die 140 within each of the power transistor submodules 100A and 100B are connected together in parallel, more power transistor submodules 100 can be added to double sided cooling module 400 to meet the higher power class rating or the increased switching current rating.

In the illustrated embodiment, semiconductor die 140 for each power transistor submodule 100A and 100B can be a Silicon Metal Oxide Semiconductor Field-effect Transistor (Si MOSFET), an Insulated Gate Bipolar Transistor (IGBT), a Gallium Nitride (GaN) power transistor or a Silicon Carbide MOSFET (SiC MOSFET). In other embodiments, semiconductor die 140 for each power transistor submodule 100A and 100B can be other suitable types of power devices. In one embodiment, semiconductor die 140 for each power transistor submodule 100A and 100B is a SiC MOSFET, and the top side load path contact 142 is a source contact, the top side control contact 144 is a gate contact, and the bottom side load path contact 146 is a drain contact. In one embodiment, the semiconductor die 140 for each power transistor submodule 100A and 100B is an IGBT, and the top side load path contact 142 is an emitter contact, the top side control contact 144 is a gate contact, and the bottom side load path contact 146 is a collector contact. In one embodiment, the first wires 118 are Cu first wires 118 and the second wires 128 are Cu second wires 128.

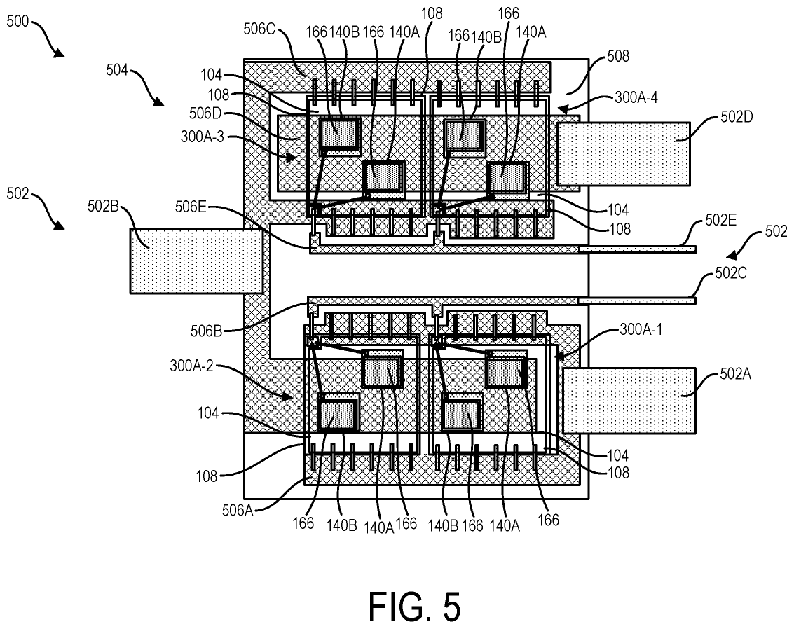

FIG. 5 illustrates an embodiment of a partial top view of a double sided cooling module at 500 that includes submodules 300A connected together in a half-bridge configuration (See also, FIG. 3A). The submodules 300A each include two semiconductor die 140A and 140B. The electrical connections for each semiconductor die 140A and 140B are described with respect to FIGS. 1A-1B and 3A and semiconductor die 140. In other embodiments, submodule 300A can include one or more than two semiconductor die 140. In the illustrated embodiment, each semiconductor die 140A and 140B is a SiC MOSFET, and the top side load path contact 142 is a source contact, the top side control contact 144 is a gate contact, and the bottom side load path contact 146 is a drain contact (See also, FIGS. 1A-1B). Each submodule 300A has the top side load path contacts 142 electrically coupled together and the bottom side load path contacts 146 electrically coupled together (See also, FIGS. 1A-1B and 3A).

Double sided cooling module 500 includes a leadframe 502 with a top Direct Copper Bonded (DCB) substrate 504 that includes a top metal layer (not illustrated) and a bottom metal layer 506 that are separated by an insulation layer 508. The bottom metal layer 506 is illustrated in FIG. 5 as 506A, 506B, 506C, 506D and 506E which are electrically isolated from each other. The leads of leadframe 502 are illustrated in FIG. 5 as 502A, 502B and 502D.

Double sided cooling module 500 includes four power transistor submodules 300A that are described with respect to FIGS. 1A-2 and FIG. 3A. The four power transistor submodules 300A are illustrated as 300A-1, 300A-2, 300A-3 and 300A-4. The power transistor submodules 300A-1 and 300A-2 with SiC MOSFETs 140A and 140B together form a high side SiC MOSFET for the half-bridge, and the power transistor submodules 300A-3 and 300A-4 with SiC MOSFETs 140A and 140B together form a low side SiC MOSFET for the half-bridge.

Each power transistor submodule 300A-1, 300A-2, 300A-3 and 300A-4 includes a bottom Direct Copper Bonded (DCB) substrate 102 that includes a top metal layer 104 and a bottom metal layer 106 that are separated by an insulation layer 108 (See also, FIGS. 1A-1B and 3A). For power transistor submodules 300A-1 and 300A-2, the bottom side load path contact 146 or drain contact for SiC MOSFETs 140A and 140B are each coupled via top metal layer 104 of the bottom DCB substrate 102 to the bottom metal layer 506A of the top DCB substrate 504 (See also, FIGS. 1A-1B and 3A). Bottom metal layer 506A is electrically coupled to lead 502A which may be connected to a positive voltage. For power transistor submodules 300A-1 and 300A-2, the top side control contact 144 is a gate contact for SiC MOSFETs 140A and 140B and are each electrically coupled to bottom metal layer 506B of the top DCB substrate 504 (See also, FIGS. 1A-1B and 3A). Bottom metal layer 506B is electrically coupled to lead 502C which is a control or gate input for power transistor submodules 300A-1 and 300A-2. For power transistor submodules 300A-1 and 300A-2, the top side load path contact or source contact for SiC MOSFETs 140A and 140B are each electrically coupled via a top side 166 of spacer 160 to the bottom metal layer 506C of the top DCB substrate 504 (See also, FIGS. 1A-1B and 3A). Bottom metal layer 506C is electrically coupled to lead 502B which is an output of the half-bridge formed by double sided cooling module 500. For power transistor submodules 300A-3 and 300A-4, the bottom side load path contact 146 or drain contact for SiC MOSFETs 140A and 140B are each coupled via bottom metal layer 104 of the bottom DCB substrate 102 to the bottom metal layer 506C of the top DCB substrate 504 (See also, FIGS. 1A-1B and 3A). Bottom metal layer 506C is electrically coupled to lead 502B which is an output of the half-bridge formed by double sided cooling module 500. For power transistor submodules 300A-3 and 300A-4, the top side control contact 144 is a gate contact for SiC MOSFETs 140A and 140B and are each electrically coupled to bottom metal layer 506E of the top DCB substrate 504 (See also, FIGS. 1A-1B and 3A). Bottom metal layer 506E is electrically coupled to lead 502E which is a control or gate input for power transistor submodules 300A-3 and 300A-4. For power transistor submodules 300A-3 and 300A-4, the top side load path contact or source contact for SiC MOSFETs 140A and 140B are each electrically coupled via a top side 166 of spacer 160 to the bottom metal layer 506D of the top DCB substrate 504 (See also, FIGS. 1A-1B and 3A). Bottom metal layer 506D is electrically coupled to lead 502D which may be connected to a ground connection.

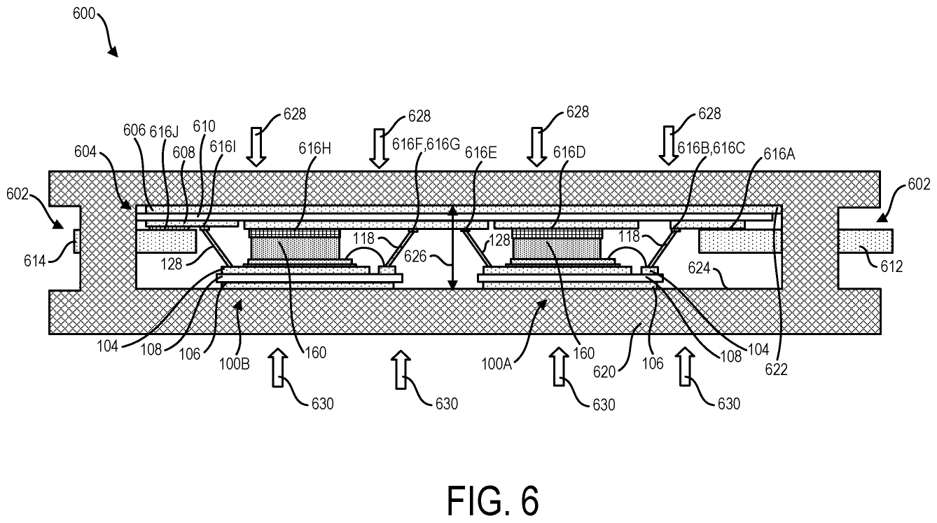

FIG. 6 illustrates an embodiment of a method of forming a double sided cooling module at 600. FIG. 6 illustrates an embodiment of forming the double sided cooling module 400 illustrated in FIG. 4. In the illustrated embodiment, the method includes providing a leadframe 602 with a top Direct Copper Bonded (DCB) substrate 604 that includes a top metal layer 606 and a bottom metal layer 608 that are separated by an insulation layer 610. Leadframe 602 includes lead 612 and lead 614 that are attached to the bottom metal layer 608. The method includes providing one or two or more power transistor submodules 100 (See also, FIGS. 1A-2). In the illustrated embodiment, the method includes providing two power transistor submodules 100 which are illustrated as power transistor submodule 100A and power transistor submodule 100B. Referring to FIGS. 1A-2, each one of the power transistor submodules 100A and 100B includes a bottom Direct Copper Bonded (DCB) substrate 102 that includes a top metal layer 104 and a bottom metal layer 106 that are separated by an insulation layer 108. The top metal layer 104 of the bottom DCB substrate 102 has a first side 110, a second side 112 and a center 114 equidistant from the first side 110 and the second side 112 in a direction parallel with a plane 116 of the top metal layer 104 of the bottom DCB substrate 102. The bottom DCB substrate 102 includes spaced-apart row of first wires 118 as illustrated at 120 that each have a top end 122 and a bottom end 124. The bottom end 124 of each of the first wires 118 is attached to the top metal layer 104 of the bottom DCB substrate 102 proximate to the first side 110 of the top metal layer 104 of the bottom DCB substrate 102. The bottom DCB substrate 102 includes a spaced-apart row of second wires 128 as illustrated at 130 that each have a top end 132 and a bottom end 134. The bottom end 134 of each of the second wires 128 is attached to a die pad portion 150 of the top metal layer 104 of the bottom DCB substrate 102 proximate to the second side 112 of the top metal layer 104 of the bottom DCB substrate 102. A semiconductor die 140 includes a top side load path contact 142, a top side control contact 144 and a bottom side load path contact 146. The bottom side load path contact 146 is attached to a top surface 148 of the die pad portion 150 of the top metal layer 104. The top side control contact 144 is electrically coupled via at least one bond wire 152 to a top surface 154 of a control pad portion 156 of the top metal layer 104 of the bottom DCB substrate 102. The control pad portion 156 is electrically isolated from the die pad portion 150. At least one of the first wires 118 as illustrated at 118A is attached to the control pad portion 156 of the top metal layer 104 of the bottom DCB substrate 102, and other ones of the first wires 118 as illustrated at 118B are attached to the die pad portion 150 of the top metal layer 104 of the bottom DCB substrate 102. An electrically conductive and thermally conductive spacer 160 is over the semiconductor die 140 and is attached to the top side load path contact 142 of the semiconductor die 140.

The method includes printing a solder on selected portions of the bottom metal layer 608 of the top DCB substrate 604. The selection portions are illustrated as 616A, 616B, 616C, 616D, 616E, 616F, 616G, 616H, 616I and 616J. The method includes placing the leadframe 602 such that lead 612 contacts solder portion 616A and lead 614 contacts solder portion 616J. The method includes placing the power transistor submodules 100A and 100B such that a top side 166 of the spacer 160 for power transistor submodule 100A contacts solder portion 616D and a top side 166 of the spacer 160 for power transistor submodule 100B contacts solder portion 616H (See also, FIGS. 1A-1B and 3A). Placing the power transistor submodules 100A and 100B further includes placing the top end 122 of a one of the first wires 118 for power transistor submodule 100A against solder portion 616B, placing the top ends 122 of the other ones of the first wires 118 for power transistor submodule 100A against solder portion 616C, and placing the top end 132 of the second wires 128 for power transistor submodule 100A against solder portion 616E (See also, FIGS. 1A-1B and 3A). Placing the power transistor submodules 100A and 100B further includes placing the top end 122 of a one of the first wires 118 for power transistor submodule 100B against solder portion 616F, placing the top ends 122 of the other ones of the first wires 118 for power transistor submodule 100B against solder portion 616G, and placing the top end 132 of the second wires 128 for power transistor submodule 100B against solder portion 616I (See also, FIGS. 1A-1B and 3A).

The method includes reflowing the solder portions 616A, 616B, 616C, 616D, 616E, 616F, 616G, 616H, 616I and 616J under a pressure from a top metal piece 618 and a bottom metal piece 620 that are coplanar and have a distance between a lower surface 622 of the top metal piece 618 and an upper surface 624 of the bottom metal piece 620 that corresponds to a required thickness illustrated at 626 for double sided cooling module 600 and the double sided cooling module 400 illustrated in FIG. 4. The top metal piece 618 applies a downward pressure as illustrated at 628 against the top metal layer 606 of the top DCB substrate 604, and the bottom metal piece 620 applies an upward pressure as illustrated at 630 against the bottom metal layer 106 of the bottom DBC substrate 102 for the power transistor submodules 100A and 100B. The reflowing of the solder portions 616B, 616C, 616D, 616E, 616F, 616G, 616H and 616I under a pressure from a top metal piece 618 and a bottom metal piece 620 for each power transistor submodules 100A and 100B attaches the top side 166 of the spacer 160, the top end 122 of the first wires 118 and the top end 132 of the second wires 128 to the bottom metal layer 608 of the top DCB substrate 604. The reflowing of the solder portions 616A and 616J attaches leads 612 and 614 of leadframe 602 to the bottom metal layer 608 of the top DCB substrate 604.

In the illustrated embodiment, and referring to FIGS. 1A-2, a first angle 168 of each of the first wires 118 in a first direction 170 from the center 114 to the first side 110 of the top metal layer 104 relative to the plane 116 of the first metal layer 104 is greater than 45 degrees and less than 90 degrees. A second angle 172 of each of the second wires 128 in a second direction 174 from the center 114 to the second side 112 of the top metal layer 104 relative to the plane 116 of the top metal layer 104 is greater than 45 degrees and less than 90 degrees. In one embodiment, the first angle 168 is equal to the second angle 172.

In the illustrated embodiment, reflowing the solder portions 616A, 616B, 616C, 616D, 616E, 616F, 616G, 616H, 616I and 616J under a pressure from the top metal piece 618 and the bottom metal piece 620 includes the first wires 118 and the second wires 128 functioning as compression springs for the power transistor submodules 100A and 100B that provide a force between the bottom metal layer 608 of the top DCB substrate 604 and the top metal layer 104 of the bottom DCB substrate 102 for each one of the power transistor submodules 100A and 100B to press the top metal layer 606 of the top DBC substrate 604 against the lower surface 622 of the top metal piece 618 and to press the bottom metal layer 106 of the bottom DCB substrate 102 for power transistor submodules 100A and 100B against the upper surface 624 of the bottom metal piece 620 to provide the required thickness 626 of the double sided cooling module 400.

In one embodiment, providing the two or more power transistor submodules 100 which are illustrated as power transistor submodule 100A and power transistor submodule 100B further includes first electrically testing each one of a plurality of power transistor submodules 100 to identify the ones of the plurality of power transistor submodules 100 that meet a desired electrical specification for the power transistor submodules 100. The method includes providing the ones of the plurality of power transistor submodules 100 that meet the desired electrical specifications as the power transistor submodule 100A and power transistor submodule 100B.

The method includes encapsulation a portion of the leadframe 602/402, the top DBC substrate 604/404 and the two or more power modules 100 which are illustrated as power transistor submodule 100A and power transistor submodule 100B with a mold compound 422 such that a top surface 424 of the top metal layer 406 of the top DBC substrate 404 is exposed at a top surface 426 of the mold compound 422 and a bottom surface 136 of the bottom metal layer 106 of the bottom DBC substrate 102 for each power transistor submodule 100A and 100B is exposed at a bottom surface 428 of the mold compound 422 (See also, FIG. 4).

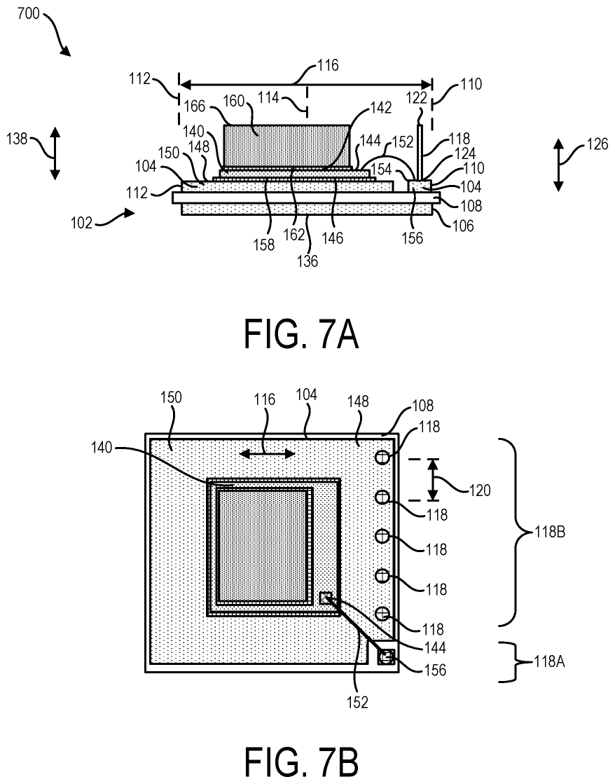

FIGS. 7A-7B illustrate an embodiment of a side view and a top view of a submodule at 700. Submodule 700 is illustrated and described with respect to submodule 100 in FIGS. 1A-2. A difference between submodule 700 and submodule 100 is that submodule 700 has a first angle 168 for each of the first wires 118 relative to the plane 116 of the first metal layer 104 that is approximately equal to 90 degrees (See also, FIG. 2). Another difference between submodule 700 and submodule 100 is that submodule 700 does not include the second wires 128 (See also, FIG. 1A-2).

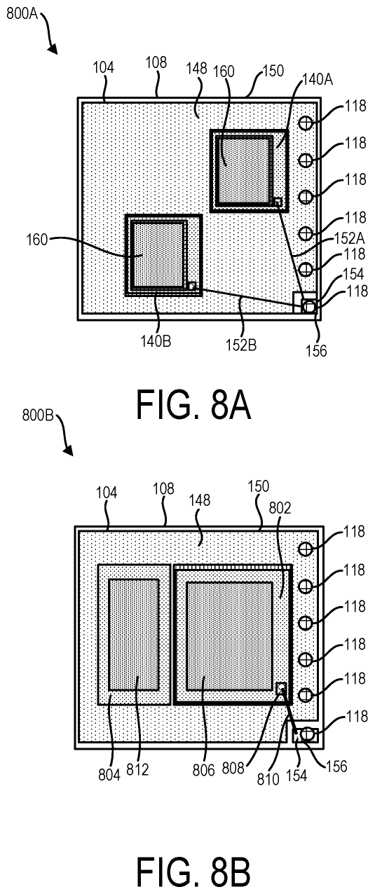

FIGS. 8A-8B illustrate embodiments of top views of a submodule at 800A and 800B. Submodules 800A and 800B utilize a DCB substrate 102 and first wires 118 as illustrated in FIGS. 7A-7B. Submodules 800A and 800B have a first angle 168 of each of the first wires 118 relative to the plane 116 of the first metal layer 104 that is approximately equal to 90 degrees (See also, FIGS. 2 and 7A-7B).

Referring to FIG. 8A, submodule 800A includes two semiconductor die 140A and 140B connected in parallel as opposed to one semiconductor die 140 as illustrated in FIGS. 1A-1B. The electrical connections for semiconductor die 140A and 140B are described with respect to FIGS. 1A-1B and semiconductor die 140. In other embodiments, submodule 800A can include more than two semiconductor die 140.

Referring to FIG. 8B, Submodule 800B includes an IGBT 802 and an anti-parallel diode 804. IGBT 802 includes a top side load path contact which is an emitter contact that is attached to and electrically coupled to a spacer 806. IGBT 802 includes a top side control contact 808 which is a gate contact which is electrically coupled via at least one bond wire 810 to a top surface 154 of a control pad portion 156 of the top metal layer 104. IGBT 802 includes a bottom side load path contact which is a collector contact and which is attached to and electrically coupled to a top surface 148 of a die pad portion 150 of the top metal layer 104. Anti-parallel diode includes an anode contact which is attached to and electrically coupled to a spacer 812. Anti-parallel diode includes a cathode contact which is attached to and electrically coupled to the top surface 148 of the die pad portion 150 of the top metal layer 104.

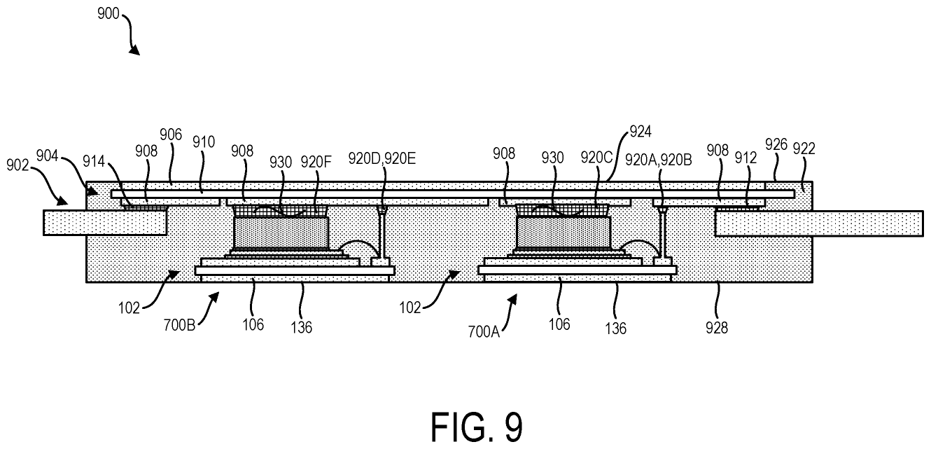

FIG. 9 illustrates an embodiment of a double sided cooling module with two submodules at 900. Double sided cooling module 900 includes a leadframe 902 with a top Direct Copper Bonded (DCB) substrate 904 that includes a top metal layer 906 and a bottom metal layer 908 that are separated by an insulation layer 910. The leadframe 902 is attached to and electrically coupled to the bottom metal layer 908 via solder connections 912 and 914. Double sided cooling module 900 includes two power transistor submodules 700 which are illustrated as 700A and 700B. Power transistor submodule 700A and 700B are described with respect to FIG. 7. In other embodiments, double sided cooling module 900 can include one or more than two power transistor submodules 700.

In the illustrated embodiment, and referring also to FIGS. 1A-2 and FIG. 7, power transistor submodules 700A and 700B each include a bottom DCB substrate 102 that includes a top metal layer 104 and a bottom metal layer 106 that are separated by an insulation layer 108. The top metal layer 104 has a first side 110, a second side 112 and a center 114 equidistant from the first side 110 and the second side 112 in a direction parallel with a plane 116 of the top metal layer 104. A spaced-apart row of first wires 118 as illustrated at 120 each have a top end 122 and a bottom end 124. A first angle 168 of each of the first wires 118 relative to the plane 116 of the first metal layer 104 is approximately equal to 90 degrees. Referring also to FIG. 7, power transistor submodules 700A and 700B each include a semiconductor die 140 that includes a top side load path contact 142, a top side control contact 144 and a bottom side load path contact 146, where the bottom side load path contact 146 is attached to a top surface 148 of a die pad portion 150 of the top metal layer 104 and the top side control contact 144 is electrically coupled via at least one bond wire 152 to a top surface 154 of a control pad portion 156 of the top metal layer 104. At least one of the first wires 118 is attached to the control pad portion 156 of the top metal layer 104, and other ones of the first wires 118 are attached to the die pad portion 150 of the top metal layer 104. An electrically conductive and thermally conductive spacer 160 is over the semiconductor die 140 and is attached to the top side load path contact 142 of the semiconductor die 140.

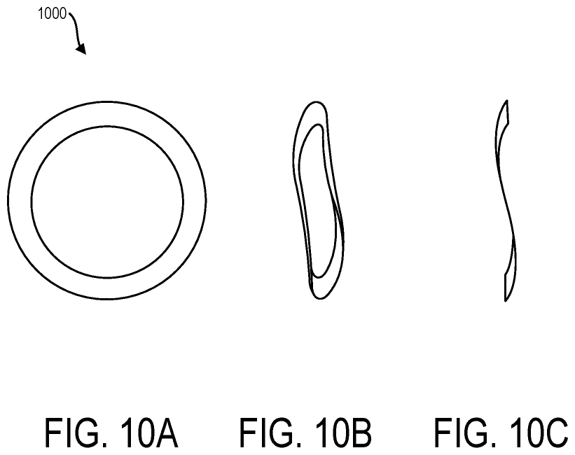

In the illustrated embodiment, least one of the first wires 118 for each power transistor submodule 700A and 700B is conductively coupled to and attached to the control pad portion 156 of the top metal layer 104 of the bottom DCB substrate 102 and a top end 122 of the each one of the first wires 118 is conductively coupled to and attached to the bottom metal layer 908 of the top DCB substrate 904 via respective solder connections 920A and 920D to electrically couple the top side control contact 144 of semiconductor die 140 to the bottom metal layer 908 of the top DCB substrate 904. Other ones of the first wires 118 for each power transistor submodule 700A and 700B are conductively coupled to and attached to the die pad portion 150 of the top metal layer 104 of the bottom DCB substrate 102 and a top end 122 of the each one of the first wires 118 is conductively coupled to and attached to the bottom metal layer 908 of the top DCB substrate 904 via respective solder connections 920B and 920E to electrically couple the bottom side load path contact 146 of semiconductor die 140 to the bottom metal layer 908 of the top DCB substrate 904. The spacer 160 for each power transistor submodule 700A and 700B is attached at a top side 166 to the bottom metal layer 908 of the top DCB substrate 904 to electrically couple the top side load path contact 142 of semiconductor die 140 to the bottom metal layer 908 of the top DCB substrate 904 via respective solder connections 920C and 920F. 15. Each one of the two power transistor submodules 700A and 700B includes a spring washer 930 between a top side of the spacer 160 and the bottom metal layer 908 of the top DCB substrate 904. Spring washer 930 is embedded within solder connections 920C and 920F for respective power transistor submodule 700A and 700B and are used during formation of double sided cooling module 900 where reflowing the solder by providing a force between the bottom metal layer 908 of the top DBC substrate 904 and the top side 166 of the spacer 160 for power transistor submodule 700A and 700B provides the required thickness of the double sided cooling module 900 (See also, FIG. 10).

In the illustrated embodiment, a mold compound 922 encapsulates a portion of the leadframe 902, the top DBC substrate 904 and power transistor submodules 700A and 700B such that a top surface 924 of the top metal layer 906 of the top DBC substrate 904 is exposed at a top surface 926 of the mold compound 922. A bottom surface 136 of the bottom metal layer 106 of the bottom DBC substrate 102 for each power transistor submodule 700A and 700B is exposed at a bottom surface 928 of the mold compound 922.

Although the different portions of bottom metal layer 908 of the top DCB substrate 904 are collectively referred to as bottom metal layer 908, it is understood that in one embodiment, the top side load path contact 142, a top side control contact 144 and a bottom side load path contact 146 of semiconductor die 140 within each of the transistor submodules 700A and 700B are connected in a parallel arrangement. In one embodiment, the one of the first wires 118 for each power transistor submodule 700A and 700B are conductively coupled to and attached to a first portion of bottom metal layer 908 of the top DCB substrate 904, the other ones of the first wires 118 for each power transistor submodule 700A and 700B are conductively coupled to and attached to a second portion of bottom metal layer 908 of the top DCB substrate 904 that is electrically isolated from the first portion of the bottom metal layer 904, and the spacer 160 is conductively coupled to and attached to a third portion of bottom metal layer 908 of the top DCB substrate 904 that is electrically isolated from both the first portion and the second portion of the bottom metal layer 908.

In the illustrated embodiment, semiconductor die 140 for each power transistor submodule 700A and 700B can be a Silicon Metal Oxide Semiconductor Field-effect Transistor (Si MOSFET), an Insulated Gate Bipolar Transistor (IGBT), a Gallium Nitride (GaN) power transistor or a Silicon Carbide MOSFET (SiC MOSFET). In other embodiments, semiconductor die 140 for each power transistor submodule 700A and 700B can be other suitable types of power devices. In one embodiment, semiconductor die 140 for each power transistor submodule 700A and 700B is a SiC MOSFET, and the top side load path contact 142 is a source contact, the top side control contact 144 is a gate contact, and the bottom side load path contact 146 is a drain contact. In one embodiment, the semiconductor die 140 for each power transistor submodule 700A and 700B is an IGBT, and the top side load path contact 142 is an emitter contact, the top side control contact 144 is a gate contact, and the bottom side load path contact 146 is a collector contact. In one embodiment, the first wires 118 are Cu first wires 118.

FIGS. 10A-10C illustrate an embodiment at 1000 of the spring washer 930 illustrated in FIG. 9. In the illustrated embodiment, spring washer 930 is a wave washer 930. FIG. 10A illustrates a top view of wave washer 930, FIG. 10B illustrates a perspective view of wave washer 930, and FIG. 10C illustrates a side view of wave washer 930. The spring rate or spring constant of wave washer 930 represents the amount of force it takes to compress wave washer 930. In one embodiment, the spring rate of wave washer 930 is approximately linear between 20% and 80% of available deflection or compression of wave washer 930. In other embodiment, other suitable types of spring washers may be used such as curved washers or disc washers. In other embodiments, other suitable elastic metal objects may be used in place of washer 930 or in combination with washer 930 that include, but are not limited to, an undulated wire having a shift in amplitude in the direction of compression of the undulated wire. In one embodiment, the undulated wire has a sinusoidal undulation.

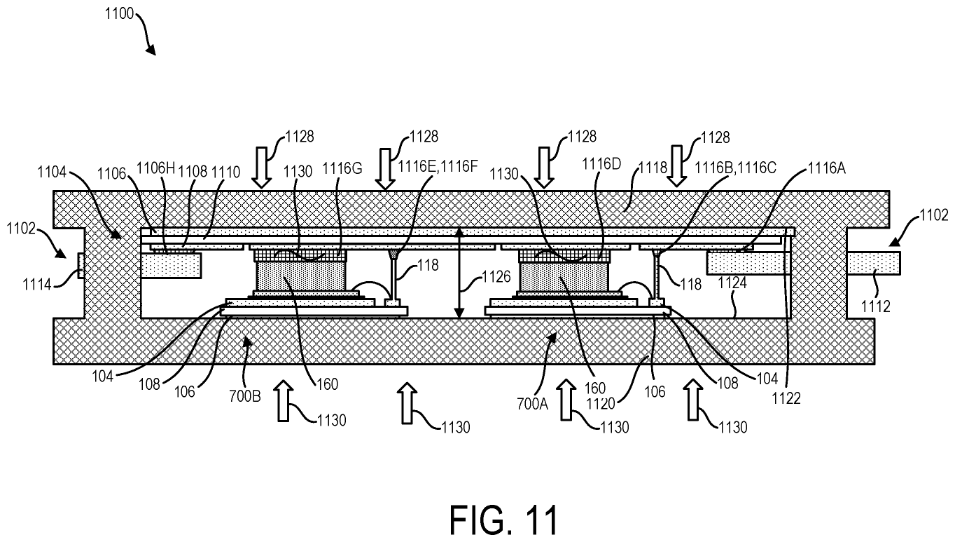

FIG. 11 illustrates an embodiment of a method of forming a double sided cooling module at 1100. FIG. 11 illustrates an embodiment of forming the double sided cooling module 900 illustrated in FIG. 9. In the illustrated embodiment, the method includes providing a leadframe 1102 with a top Direct Copper Bonded (DCB) substrate 1104 that includes a top metal layer 1106 and a bottom metal layer 1108 that are separated by an insulation layer 1110. Leadframe 1102 includes lead 1112 and lead 1114 and is attached to the bottom metal layer 1108. The method includes providing one or two or more power transistor submodules 700 (See also, FIGS. 7A-7B). In the illustrated embodiment, the method includes providing two power transistor submodules 700 which are illustrated as power transistor submodule 700A and power transistor submodule 700B. Referring to FIGS. 7A-7B, each one of the power transistor submodules 700A and 700B includes a bottom Direct Copper Bonded (DCB) substrate 102 that includes a top metal layer 104 and a bottom metal layer 106 that are separated by an insulation layer 108. The top metal layer 104 of the bottom DCB substrate 102 has a first side 110, a second side 112 and a center 114 equidistant from the first side 110 and the second side 112 in a direction parallel with a plane 116 of the top metal layer 104 of the bottom DCB substrate 102. The bottom DCB substrate 102 includes spaced-apart row of first wires 118 as illustrated at 120 each have a top end 122 and a bottom end 124. The bottom end 124 of each of the first wires 118 is attached to the top metal layer 104 of the bottom DCB substrate 102 proximate to the first side 110 of the top metal layer 104 of the bottom DCB substrate 102. A semiconductor die 140 includes a top side load path contact 142, a top side control contact 144 and a bottom side load path contact 146. The bottom side load path contact 146 is attached to a top surface 148 of a die pad portion 150 of the top metal layer 104. The top side control contact 144 is electrically coupled via at least one bond wire 152 to a top surface 154 of a control pad portion 156 of the top metal layer 104 of the bottom DCB substrate 102. The control pad portion 156 is electrically isolated from the die pad portion 150. At least one of the first wires 118 as illustrated at 118A is attached to the control pad portion 156 of the top metal layer 104 of the bottom DCB substrate 102, and other ones of the first wires 118 as illustrated at 118B are attached to the die pad portion 150 of the top metal layer 104 of the bottom DCB substrate 102. An electrically conductive and thermally conductive spacer 160 is over the semiconductor die 140 and is attached to the top side load path contact 142 of the semiconductor die 140.

The method includes printing a solder on selected portions of the bottom metal layer 1108 of the top DCB substrate 1104. The selection portions are illustrated as 1116A, 1116B, 1116C, 1116D, 1116E, 1116F, 1116G and 1116H. The method includes placing the leadframe 1102 such that lead 1112 contacts solder portion 1116A and lead 1114 contacts solder portion 1116H. The method includes placing the power transistor submodules 700A and 700B such that a top side 166 of the spacer 160 for power transistor submodule 700A contacts solder portion 1116D and a top side 166 of the spacer 160 for power transistor submodule 700B contacts solder portion 1116G. Placing the power transistor submodules 700A and 700B further includes placing the top end 122 of a one of the first wires 118 for power transistor submodule 700A against solder portion 1116B and placing the top ends 122 of the other ones of the first wires 118 for power transistor submodule 700A against solder portion 1116C. Placing the power transistor submodules 700A and 700B further includes placing the top end 122 of a one of the first wires 118 for power transistor submodule 700B against solder portion 1116E and placing the top ends 122 of the other ones of the first wires 118 for power transistor submodule 700B against solder portion 1116F.

The method includes reflowing the solder portions 1116A, 1116B, 1116C, 1116D, 1116E, 1116F, 1116G and 1116H under a pressure from a top metal piece 1118 and a bottom metal piece 1120 that are coplanar and have a distance between a lower surface 1122 of the top metal piece 1118 and an upper surface 1124 of the bottom metal piece 1120 that corresponds to a required thickness illustrated at 1126 for the double sided cooling module 700 illustrated in FIG. 7. The top metal piece 1118 applies a downward pressure as illustrated at 1128 against the top metal layer 1106 of the top DCB substrate 1104, and the bottom metal piece 1120 applies an upward pressure as illustrated at 1130 against the bottom metal layer 106 of the bottom DBC substrate 102 for the power transistor submodules 700A and 700B. The reflowing of the solder portions 1116B, 1116C, 1116D, 1116E, 1116F and 1116G under a pressure from the top metal piece 1118 and the bottom metal piece 1120 for each power transistor submodule 700A and 700B attaches the top side 166 of the spacer 160, the top end 122 of the first wires 118 and the top end 132 of the second wires 128 to the bottom metal layer 1108 of the top DCB substrate 1104. The reflowing of the solder portions 1116A and 1116H attaches leads 1112 and 1114 of leadframe 1102 to the bottom metal layer 1108 of the top DCB substrate 1104. In the illustrated embodiment, and referring to FIG. 2, a first angle 168 of each of the first wires 118 have a first angle relative to the plane 116 of the top metal layer 104 of the bottom DCB substrate 102 that is approximately equal to 90 degrees.

In the illustrated embodiment, placing the two power transistor submodules 700A and 700B such that the top side 166 of the spacer 160 contacts respective solder portions 1116D and 1116G includes placing a spring washer 1130 between the top side 166 of the spacer 160 and the bottom metal layer 1108 and within the respective solder portions 1116D and 1116G for the power transistor submodules 700A and 700B. Reflowing the respective solder portions 1116D and 1116G for the power transistor submodules 700A and 700B under the pressure from the top metal piece 1118 and the bottom metal piece 1120 includes the spring washer 1130 for the power transistor submodules 700A and 700B being compressed and providing a force between the bottom metal layer 1108 of the top DBC substrate 1104 and the top side 166 of the spacer 160 for each one of the power transistor submodules 700A and 700B to press the top metal layer 1106 of the top DBC substrate 1104 against the lower surface 1122 of the top metal piece 1118 and to press the bottom metal layer 106 of the bottom DCB substrate 102 for each one of the power transistor submodules 700A and 700B against the upper surface 1124 of the bottom metal piece 1120 to provide the required thickness 1126 of the double sided cooling module 900.

In one embodiment, providing the two or more power transistor submodules 100 which are illustrated as power transistor submodule 700A and power transistor submodule 700B further includes first electrically testing each one of a plurality of power transistor submodules 700 to identify the ones of the plurality of power transistor submodules 700 that meet a desired electrical specification. The method includes providing the ones of the plurality of power transistor submodules 700 that meet the desired electrical specifications as the power transistor submodule 700A and power transistor submodule 700B.

The method includes encapsulating a portion of the leadframe 1102/902, the top DBC substrate 1104/904 and the power transistor submodules 700A and 700B with a mold compound 922 such that a top surface 924 of the top metal layer 906 of the top DBC substrate 904 is exposed at a top surface 926 of the mold compound 922 and a bottom surface 136 of the bottom metal layer 106 of the bottom DBC substrate 102 for each one of the power transistor submodules 700A and 700B is exposed at a bottom surface 928 of the mold compound 922 (See also, FIG. 9).

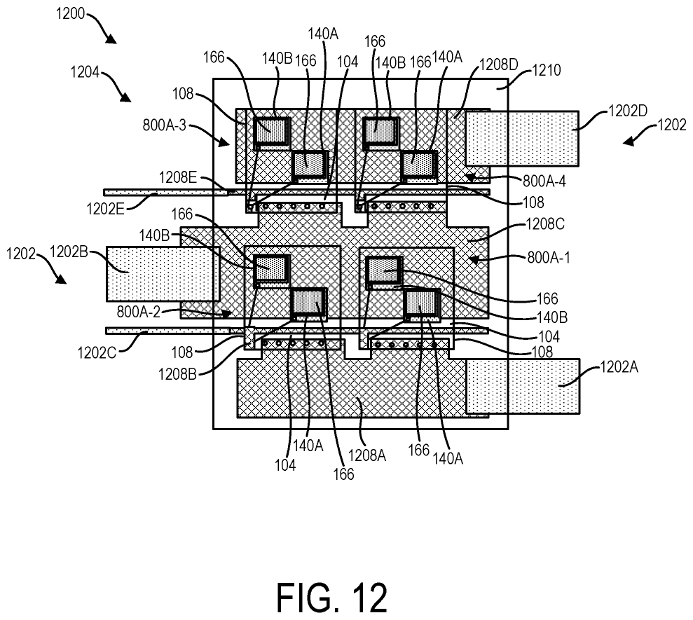

FIG. 12 illustrates an embodiment of a partial top view of double sided cooling module at 1200 that includes submodules 800A connected together in a half-bridge configuration. The submodules 800A each include two semiconductor die 140A and 140B. The electrical connections for each semiconductor die 140A and 140B are described with respect to FIGS. 7A-8A. In other embodiments, submodule 800A can include one or more than two semiconductor die 140. In the illustrated embodiment, the semiconductor die 140A and 140B are SiC MOSFETs. Each semiconductor die 140A and 140B includes a top side load path contact 142 which is a source contact, a top side control contact 144 which is a gate contact, and a bottom side load path contact 146 which is a drain contact (See also, FIGS. 7A-8A). Each module 800A has the top side load path contacts 142 electrically coupled together and the bottom side load path contacts 146 electrically coupled together (See also, FIGS. 7A-8A).

The double sided cooling module 1200 includes a leadframe 1202 with a top Direct Copper Bonded (DCB) substrate 1204 that includes a top metal layer (not illustrated) and a bottom metal layer 1208 that are separated by an insulation layer 1210. The bottom metal layer 1208 is illustrated in FIG. 12 as 1208A, 1208B, 1208C, 1208D and 1208E which are electrically isolated from each other. The leadframe 1202 is attached to and electrically coupled to the bottom metal layer 1208. The leads of leadframe 1202 are illustrated in FIG. 12 as 1202A, 1202B and 1202D. Double sided cooling module 1200 includes four power transistor submodules 800A that are described with respect to FIGS. 7A-8A. The four power transistor submodules 800A are illustrated as 800A-1, 800A-2, 800A-3 and 800A-4. The power transistor submodules 800A-1 and 800A-2 with SiC MOSFETs 140A and 140B together form a high side SiC MOSFET for the half-bridge, and the power transistor submodules 800A-3 and 800A-4 with SiC MOSFETs 140A and 140B together form a low side SiC MOSFET for the half-bridge.

Each power transistor submodule 800A-1, 800A-2, 800A-3 and 800A-4 includes a bottom Direct Copper Bonded (DCB) substrate 102 that includes a top metal layer 104 and a bottom metal layer 106 that are separated by an insulation layer 108 (See also, FIGS. 7A-8A). For power transistor submodules 800A-1 and 800A-2, the bottom side load path contact 146 or drain contact for SiC MOSFETs 140A and 140B are each coupled via top metal layer 104 of the bottom DCB substrate 102 to the bottom metal layer 1208A of the top DCB substrate 1204. Bottom metal layer 1208A is electrically coupled to lead 1202A which may be connected to a positive voltage. For power transistor submodules 800A-1 and 800A-2, the top side control contact 144 is a gate contact for SiC MOSFETs 140A and 140B and are each electrically coupled to bottom metal layer 1208B of the top DCB substrate 1204. Bottom metal layer 1208B is electrically coupled to lead 1202C which is a control or gate input for power transistor submodules 800A-1 and 800A-2. For power transistor submodules 800A-1 and 800A-2, the top side load path contact or source contact for SiC MOSFETs 140A and 140B are each electrically coupled via a top side 166 of spacer 160 to the bottom metal layer 1208C of the top DCB substrate 1204. Bottom metal layer 1208C is electrically coupled to lead 1202B which is an output of the half-bridge formed by double sided cooling module 1200. For power transistor submodules 800A-3 and 800A-4, the bottom side load path contact 146 or drain contact for SiC MOSFETs 140A and 140B are each coupled via top metal layer 104 of the bottom DCB substrate 102 to the bottom metal layer 1208C of the top DCB substrate 1204. Bottom metal layer 1208C is electrically coupled to lead 1202B which is an output of the half-bridge formed by double sided cooling module 1200. For power transistor submodules 800A-3 and 800A-4, the top side control contact 144 is a gate contact for SiC MOSFETs 140A and 140B and are each electrically coupled to bottom metal layer 1208E of the top DCB substrate 1204. Bottom metal layer 1208E is electrically coupled to lead 1202E which is a control or gate input for power transistor submodules 800A-3 and 800A-4. For power transistor submodules 800A-3 and 800A-4, the top side load path contact or source contact for SiC MOSFETs 140A and 140B are each electrically coupled via a top side 166 of spacer 160 to the bottom metal layer 1208D of the top DCB substrate 1204. Bottom metal layer 1208D is electrically coupled to lead 1202D which may be connected to a ground connection.

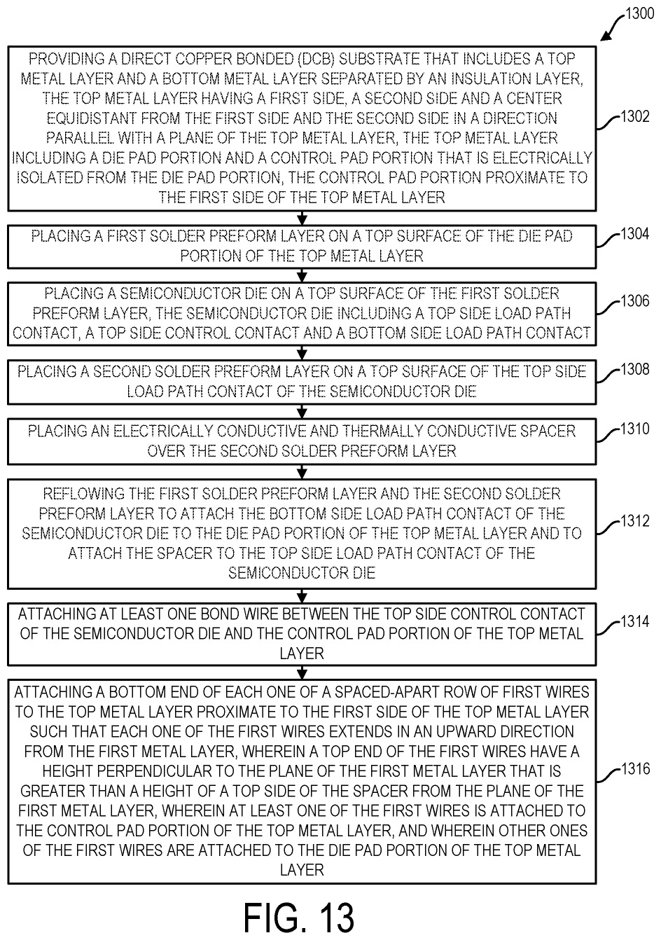

FIG. 13 illustrates an embodiment at 1300 of a method of forming a submodule. Embodiments of submodules are illustrated in FIGS. 1A-3B and in FIGS. 7A-8B. At 1302, the method includes providing a Direct Copper Bonded (DCB) substrate 102 that includes a top metal layer 104 and a bottom metal layer 106 that are separated by an insulation layer 108. The top metal layer 104 has a first side 110, a second side 112 and a center 114 equidistant from the first side 110 and the second side 112 in a direction parallel with a plane 116 of the top metal layer 104. The top metal layer of the DCB substrate 102 includes a die pad portion 150 and a control pad portion 156 that is electrically isolated from the die pad portion 150. The control pad portion 156 is proximate to the first side 110 of the top metal layer 104.

At 1304, the method includes placing a first preform solder layer 158 on a top surface 148 of the die pad portion 150 of the top metal layer 104. At 1306, the method includes placing a semiconductor die 140 on a top surface of the first solder preform layer 158. The semiconductor die 140 includes a top side load path contact 142, a top side control contact 144 and a bottom side load path contact 146. At 1308, the method includes placing a second solder preform layer 162 on a top surface of the top side load path contact 142 of the semiconductor die 140. At 1310, the method includes placing an electrically conductive and thermally conductive spacer 160 over the second solder preform layer 162. At 1312, the method includes reflowing the first solder preform layer 158 and the second solder preform layer 162 to attach the bottom side load path contact 146 of the semiconductor die 140 to the die pad portion 150 of the top metal layer 104 and to attach the spacer 160 to the top side load path contact 142 of the semiconductor die 140. At 1314, the method includes attaching at least one bond wire 152 between the top side control contact 144 of the semiconductor die 140 and a top surface 154 of a control pad portion 156 of the top metal layer 104.

At 1316, the method includes attaching a bottom end 124 of each one of a spaced-apart row of first wires 118 to the top metal layer 104 proximate to the first side 110 of the top metal layer 104. Each one of the first wires 118 extend in an upward direction as illustrated at 126 from the first metal layer 104. The top end 132 of the second wires 128 have a height 138 perpendicular to the plane 116 of the first metal layer 104 that is greater than a height 164 of the top side 166 of the spacer 160 from the plane 116 of the first metal layer 104. At least one of the first wires 118 as illustrated at 118A is attached to the control pad portion 156 of the top metal layer 104. Other ones of the first wires 118 as illustrated at 118B are attached to the die pad portion 150 of the top metal layer 104.

In some embodiments, attaching the bottom end 124 of each of the first wires 118 to the top metal layer 104 proximate to the first side 110 of the top metal layer 104 includes each one of the first wires 118 having a first angle 168 relative to the plane 116 of the top metal layer 104 that is approximately equal to 90 degrees.

In some embodiments, the method includes attaching a bottom end 134 of each one of a spaced-apart row of second wires 128 to the top metal layer 104 proximate to the second side 112 of the top metal layer 104 such that each one of the second wires 128 have a second angle 172 in a second direction 174 from the center 114 to the second side 112 of the top metal layer 104 relative to the plane 116 of the top metal layer 104 that is greater than 45 degrees and less than 90 degrees. In some embodiments, attaching a bottom end 124 of each one of a spaced-apart row of first wires 118 to the top metal layer 104 proximate to the first side 110 of the top metal layer 104 includes each one of the first wires 118 having a first angle 168 in a first direction 170 from the center 114 to the first side 110 of the top metal layer 104 relative to the plane 116 of the top metal layer 104 that is greater than 45 degrees and less than 90 degrees.

What is claimed is:

1. A submodule for a double sided cooling module, comprising:
a Direct Copper Bonded (DCB) substrate that includes a top metal layer and a bottom metal layer separated by an insulation layer, the top metal layer having a first side, a second side and a center equidistant from the first side and the second side in a direction parallel with a plane of the top metal layer;
a spaced-apart row of first wires that each have a top end and a bottom end, the bottom end of each of the first wires attached to the top metal layer proximate to the first side of the top metal layer, the first wires extending in an upward direction from the first metal layer;
a semiconductor die that includes a top side load path contact, a top side control contact and a bottom side load path contact, the bottom side load path contact attached to a top surface of a die pad portion of the top metal layer, the top side control contact electrically coupled via at least one bond wire to a top surface of a control pad portion of the top metal layer that is electrically isolated from the die pad portion, wherein at least one of the first wires is attached to the control pad portion of the top metal layer, wherein other ones of the first wires are attached to the die pad portion of the top metal layer,
an electrically conductive and thermally conductive spacer over the semiconductor die that is attached to the top side load path contact of the semiconductor die,
wherein the top end of the first wires have a height perpendicular to the plane of the first metal layer that is greater than a height of a top side of the spacer from the plane of the first metal layer.

2. The submodule of claim 1, wherein a first length between the top end and the bottom end of the first wires is approximately the same.

3. The submodule of claim 1, wherein a first angle of the first wires relative to the plane of the top metal layer is approximately equal to 90 degrees.

4. The submodule of claim 1, wherein each one of the first wires is straight and parallel with every other one of the first wires.

5. The submodule of claim 1, wherein the first wires comprise copper (Cu).

6. The submodule of claim 1, further comprising a spaced-apart row of second wires that each have a top end and a bottom end, the bottom end of each of the second wires attached to the die pad portion of the top metal layer proximate to the second side of the top metal layer, the second wires extending in an upward direction from the first metal layer, wherein the top end of the second wires have a height perpendicular to the plane of the first metal layer that is greater than the height of the top side of the spacer from the plane of the first metal layer.

7. The submodule of claim 6, wherein a first length between the top end and the bottom end of the first wires is approximately equal to a second length between the top end and the bottom end of the second wires.

8. The submodule of claim 6, wherein a first angle of each of the first wires in a first direction from the center to the first side of the top metal layer relative to the plane of the top metal layer is greater than 45 degrees and less than 90 degrees, and wherein a second angle of each of the second wires in a second direction from the center to the second side of the top metal layer relative to the plane of the top metal layer is greater than 45 degrees and less than 90 degrees.

9. The submodule of claim 8, wherein the first angle is equal to the second angle.

10. The submodule of claim 6, wherein each one of the first wires is straight and parallel with every other one of the first wires, and wherein each one of the second wires is straight and parallel with every other one of the second wires.

11. The submodule of claim 6, wherein the first wires and the second wires comprise copper (Cu).

12. The submodule of claim 1, wherein the semiconductor die comprises a device selected from a group consisting of a Silicon Metal Oxide Semiconductor Field-effect Transistor (Si MOSFET), an Insulated Gate Bipolar Transistor (IGBT), a Gallium Nitride (GaN) power transistor and a Silicon Carbide MOSFET (SiC MOSFET).

13. The submodule of claim 12, wherein the semiconductor die comprises the SiC MOSFET, and wherein the top side load path contact is a source contact, the top side control contact is a gate contact, and the bottom side load path contact is a drain contact.

14. A double sided cooling module, comprising:
a leadframe with a top Direct Copper Bonded (DCB) substrate that includes a top metal layer and a bottom metal layer separated by an insulation layer, the leadframe attached to the bottom metal layer;
two or more power transistor submodules, wherein each one of the power transistor submodules includes
a bottom DCB substrate that includes a top metal layer and a bottom metal layer separated by an insulation layer, the top metal layer of the bottom DCB substrate having a first side, a second side and a center equidistant from the first side and the second side in a direction parallel with a plane of the top metal layer of the bottom DCB substrate,
a spaced-apart row of first wires that each have a top end and a bottom end, the bottom end of each of the first wires attached to the top metal layer of the bottom DCB substrate proximate to the first side of the top metal layer of the bottom DCB substrate,
a semiconductor die that includes a top side load path contact, a top side control contact and a bottom side load path contact, the bottom side load path contact attached to a top surface of a die pad portion of the top metal layer of the bottom DCB substrate, the top side control contact electrically coupled via at least one bond wire to a top surface of a control pad portion of the top metal layer of the bottom DCB substrate that is electrically isolated from the die pad portion, wherein at least one of the first wires is attached to the control pad portion of the top metal layer of the bottom DCB substrate and to the bottom metal layer of the top DCB substrate to conductively couple the top side control contact to the bottom metal layer of the top DCB substrate, wherein other ones of the first wires are attached to the die pad portion of the top metal layer of the bottom DCB substrate and to the bottom metal layer of the top DCB substrate to electrically couple the bottom side load path contact to the bottom metal layer of the top DCB substrate,
an electrically conductive and thermally conductive spacer over the semiconductor die that is attached to the top side load path contact of the semiconductor die, wherein the spacer conductive couples the top side load path contact to the bottom metal layer of the top DCB substrate.

15. The double sided cooling module of claim 14, wherein each one of the two or more power transistor submodules further comprises a spring washer or an undulated wire between a top side of the spacer and the bottom metal layer of the top DCB substrate.

16. The double sided cooling module of claim 14, wherein for each one of the two or more power transistor submodules, a first angle of the first wires relative to the plane of the top metal layer of the bottom DCB substrate is approximately equal to 90 degrees.

17. The double sided cooling module of claim 14, wherein for each one of the two or more power transistor submodules, the first wires comprise copper (Cu).

18. The double sided cooling module of claim 14, wherein each one of the two or more power transistor submodules further comprises a spaced-apart row of second wires that each have a top end and a bottom end, the bottom end of each of the second wires attached to the top metal layer of the bottom DCB substrate proximate to the second side of the top metal layer of the bottom DCB substrate, wherein for each one of the two or more power transistor submodules, the second wires are attached to the die pad portion of the top metal layer of the bottom DCB substrate and to the bottom metal layer of the top DCB substrate to electrically couple the bottom side load path contact to the bottom metal layer of the top DCB substrate.

19. The double sided cooling module of claim 18, wherein for each one of the two or more power transistor submodules, a first angle of each of the first wires in a first direction from the center to the first side of the top metal layer of the bottom DCB substrate relative to the plane of the top metal layer of the bottom DCB substrate is greater than 45 degrees and less than 90 degrees, and wherein a second angle of the second wires in a second direction from the center to the second side of the top metal layer of the bottom DCB substrate relative to the plane of the top metal layer of the bottom DCB substrate is greater than 45 degrees and less than 90 degrees.

20. The double sided cooling module of claim 19, wherein for each one of the two or more power transistor submodules, the first angle is equal to the second angle.

21. The double sided cooling module of claim 18, wherein for each one of the two or more power transistor submodules, the first wires and the second wires comprise copper (Cu).

22. The double sided cooling module of claim 14, wherein for each one of the two or more power transistor submodules, the semiconductor die comprises a device selected from a group consisting of a Silicon Metal Oxide Semiconductor Field-effect Transistor (Si MOSFET), an Insulated Gate Bipolar Transistor (IGBT), a Gallium Nitride (GaN) power transistor and a Silicon Carbide MOSFET (SiC MOSFET).

23. The double sided cooling module of claim 22, wherein for each one of the two or more power transistor submodules, the semiconductor die is the SiC MOSFET and the top side load path contact is a source contact, the top side control contact is a gate contact, and the bottom side load path contact is a drain contact.

24. The double sided cooling module of claim 14, wherein a mold compound encapsulates a portion of the leadframe, the top DBC substrate and the two or more power modules such that a top surface of the top metal layer of the top DBC substrate is exposed at a top surface of the mold compound and a bottom surface of the bottom metal layer of the bottom DBC substrate for each one of the two or more power transistor submodules is exposed at a bottom surface of the mold compound.

25. A method of forming a submodule, comprising:
providing a Direct Copper Bonded (DCB) substrate that includes a top metal layer and a bottom metal layer separated by an insulation layer, the top metal layer having a first side, a second side and a center equidistant from the first side and the second side in a direction parallel with a plane of the top metal layer, the top metal layer including a die pad portion and a control pad portion that is electrically isolated from the die pad portion, the control pad portion proximate to the first side of the top metal layer;
placing a first solder preform layer on a top surface of the die pad portion of the top metal layer;
placing a semiconductor die on a top surface of the first solder preform layer, the semiconductor die including a top side load path contact, a top side control contact and a bottom side load path contact;
placing a second solder preform layer on a top surface of the top side load path contact of the semiconductor die;
placing an electrically conductive and thermally conductive spacer over the second solder preform layer;
reflowing the first solder preform layer and the second solder preform layer to attach the bottom side load path contact of the semiconductor die to the die pad portion of the top metal layer and to attach the spacer to the top side load path contact of the semiconductor die;
attaching at least one bond wire between the top side control contact of the semiconductor die and the control pad portion of the top metal layer; and
attaching a bottom end of each one of a spaced-apart row of first wires to the top metal layer proximate to the first side of the top metal layer such that each one of the first wires extends in an upward direction from the first metal layer, wherein a top end of the first wires have a height perpendicular to the plane of the first metal layer that is greater than a height of a top side of the spacer from the plane of the first metal layer, wherein at least one of the first wires is attached to the control pad portion of the top metal layer, and wherein other ones of the first wires are attached to the die pad portion of the top metal layer.

26. The method of claim 25, wherein attaching the bottom end of each one of the first wires to the top metal layer proximate to the first side of the top metal layer comprises each one of the first wires having a first angle relative to the plane of the top metal layer that is approximately equal to 90 degrees.

27. The method of claim 25, further comprising
attaching a bottom end of each one of a spaced-apart row of second wires to the top metal layer proximate to the second side of the top metal layer such that each one of the second wires have a second angle in a second direction from the center to the second side of the top metal layer relative to the plane of the top metal layer that is greater than 45 degrees and less than 90 degrees,
wherein attaching the bottom end of each one of the first wires to the top metal layer proximate to the first side of the top metal layer comprises each one of the first wires having a first angle in a first direction from the center to the first side of the top metal layer relative to the plane of the top metal layer that is greater than 45 degrees and less than 90 degrees.

28. A method of forming a double sided cooling module, comprising:
providing a leadframe with a top Direct Copper Bonded (DCB) substrate that includes a top metal layer and a bottom metal layer separated by an insulation layer, the leadframe attached to the bottom metal layer;
providing two or more power transistor submodules, wherein each power transistor submodule includes
a bottom DCB substrate that includes a top metal layer and a bottom metal layer separated by an insulation layer, the top metal layer of the bottom DCB substrate having a first side, a second side and a center equidistant from the first side and the second side in a direction parallel with a plane of the top metal layer of the bottom DCB substrate,
a spaced-apart row of first wires that each have a top end and a bottom end, the bottom end of each of the first wires attached to the top metal layer of the bottom DCB substrate proximate to the first side of the top metal layer of the bottom DCB substrate,
a semiconductor die that includes a top side load path contact, a top side control contact and a bottom side load path contact,
the bottom side load path contact attached to a top surface of a die pad portion of the top metal layer of the bottom DCB substrate, the top side control contact electrically coupled via at least one bond wire to a top surface of a control pad portion of the top metal layer of the bottom DCB substrate that is electrically isolated from the die pad portion, wherein at least one of the first wires is attached to the control pad portion of the top metal layer of the bottom DCB substrate, wherein other ones of the first wires are attached to the die pad portion of the top metal layer of the bottom DCB substrate,
an electrically conductive and thermally conductive spacer over the semiconductor die that is attached to the top side load path contact of the semiconductor die;
printing a solder on selected portions of the bottom metal layer of the top DCB substrate;
placing a leadframe such that portions of the leadframe contact the solder;
placing the two or more power transistor submodules such that a top side of the spacer, the top end of the one of the first wires and the top ends of the other ones of the first wires contact the solder; and
reflowing the solder under a pressure from a top metal piece and a bottom metal piece that are coplanar and have a distance between a lower surface of the top metal piece and an upper surface of the bottom metal piece that corresponds to a required thickness of the double sided cooling module, the top metal piece applying a downward pressure against the top metal layer of the top DCB substrate, the bottom metal piece applying an upward pressure against the bottom metal layer of the bottom DBC substrate for each one of the two or more power transistor submodules, the reflowing of the solder attaching the top side of the spacer, the top end of the one of the first wires and the top ends of the other ones of the first wires to the bottom metal layer of the top DCB substrate.

29. The method of claim 28, wherein
placing the two or more power transistor submodules such that the top side of the spacer contacts the solder further comprises placing a spring washer between the top side of the spacer and the solder for each one of the two or more power transistor submodules; and
wherein reflowing the solder under the pressure from the top metal piece and the bottom metal piece comprises the spring washer being compressed and providing a force between the bottom metal layer of the top DBC substrate and the top side of the spacer for each one of the two or more power transistor submodules to press the top metal layer of the top DBC substrate against the lower surface of the top metal piece and to press the bottom metal layer of the bottom DCB substrate for each one of the two or more power transistor modules against the upper surface of the bottom metal piece to provide the required thickness of the double sided cooling module.

30. The method of claim 28, further comprising:
providing for each power transistor submodule, a spaced-apart row of second wires that each have a top end and a bottom end, the bottom end of each of the second wires attached to the top metal layer of the bottom DCB substrate proximate to the second side of the top metal layer of the bottom DCB substrate, the bottom side load path contact of the semiconductor die conductively coupled to the second wires, wherein each one of the second wires for each power transistor submodule has a second angle in a second direction from the center to the second side of the top metal layer of the bottom DCB substrate relative to the plane of the top metal layer of the bottom DCB substrate that is greater than 45 degrees and less than 90 degrees, and
wherein for each power transistor submodule, each one of the first wires has a first angle in a first direction from the center to the first side of the top metal layer of the bottom DCB substrate relative to the plane of the top metal layer of the bottom DCB substrate that is greater than 45 degrees and less than 90 degrees; and
wherein reflowing the solder under the pressure from the top metal piece and the bottom metal piece comprises the first wires and the second wires functioning as compression springs for each one of the two or more power transistor submodules and providing a force between the bottom metal layer of the top DBC substrate and the top metal layer of the bottom DCB substrate for each one of the two or more power transistor submodules to press the top metal layer of the top DBC substrate against the lower surface of the top metal piece and to press the bottom metal layer of the bottom DCB substrate for each one of the two or more power transistor modules against the upper surface of the bottom metal piece to provide the required thickness of the double sided cooling module.

31. The method of claim 28, wherein providing the two or more power transistor submodules further comprises first electrically testing each one of a plurality of power transistor submodules to identify the ones of the plurality of power transistor submodules that meet a desired electrical specification for the power transistor submodules, and providing the ones of the plurality of power transistor submodules that meet the desired electrical specifications as the two or more power transistor submodules.

32. The method of claim 28, further comprising, encapsulation a portion of the leadframe, the top DBC substrate and the two or more power modules with a mold compound such that a top surface of the top metal layer of the top DBC substrate is exposed at a top surface of the mold compound and a bottom surface of the bottom metal layer of the bottom DBC substrate for each one of the two or more power transistor submodules is exposed at a bottom surface of the mold compound.
